(19) United States
(12) Patent Application Publication
(10) Pub. No.: US 2025/0314433 A1
(43) Pub. Date: Oct. 9, 2025

(54) HEAT EXCHANGE UNIT

(71) Applicants: Hyundai Motor Company, Seoul (KR); Kia Corporation, Seoul (KR)

(72) Inventors: Jea Kyoo An, Seoul (KR); Hun Keon Ko, Anyang-si (KR); Yong Kyu Yoo, Seongnam-si (KR); Kyeong Ho Cho, Anyang-si (KR); Soon Hyeong Kwon, Yongin-si (KR); Joo Young Chun, Seoul (KR); Kyung Min Kim, Uiwang-si (KR)

(21) Appl. No.: 18/787,039

(22) Filed: Jul. 29, 2024

(30) Foreign Application Priority Data
Apr. 9, 2024 (KR) 10-2024-0048157

(51) Int. Cl. F28F 1/12

(52) U.S. Cl. CPC F28F 1/12

(57) ABSTRACT

An embodiment heat exchange system includes a heat transfer member mounting part, a heat transfer member mounted on the heat transfer member mounting part and defining an internal space, a fluid supply part configured to supply a cooling fluid to the internal space, a hygroscopic member disposed in the internal space and configured to absorb the cooling fluid supplied to the internal space, a deformable member coupled to the heat transfer member and configured to be deformed in shape in response to a temperature of the heat transfer member, and a discharge flow path part configured to discharge the cooling fluid from the internal space.

### CROSS-REFERENCE TO RELATED APPLICATIONS

This application claims the benefit of Korean Patent Application No. 10-2024-0048157, filed on Apr. 9, 2024, which application is hereby incorporated herein by reference.

### TECHNICAL FIELD The present disclosure relates to a heat exchange unit.

### BACKGROUND

In general, a heat exchange unit refers to a cooler installed on a heating element having a high temperature to reduce a temperature of the heating element and temperatures of the surroundings. Various types of systems may be used as the heat exchange units.

For example, a cooling system, which produces a cooling fluid by using a compressor or pump and reduces the temperature of the heating element by using the produced cooling fluid, may be used as the heat exchange unit in the related art. An air-cooled system or the like, which directly cools the heating element by using a fan, may be used as the heat exchange unit in the related art.

However, the heat exchange units in the related art described above cool the heating elements by receiving electric power from power sources connected to the heat exchange units. For this reason, there is a problem in that the number of constituent elements and assembling processes required to install the heat exchange unit are increased, the layout is complicated, and a large amount of costs are incurred to cool the heating element.

### SUMMARY

The present disclosure relates to a heat exchange unit. Particular embodiments relate to a heat exchange unit installed in an electronic device and capable of naturally cooling the electronic device without using electric power.

The present disclosure has been made in an effort to provide a heat exchange unit capable of naturally cooling the surroundings without using electric power.

A heat exchange unit according to embodiments of the present disclosure may include a heat transfer member configured to define an internal space to which a cooling fluid is supplied, a heat transfer member mounting part on which the heat transfer member is mounted, a fluid supply part configured to supply the cooling fluid to the internal space, a hygroscopic member provided in the internal space and configured to absorb the cooling fluid supplied to the internal space, a deformable member coupled to the heat transfer member and configured to be deformed in shape in response to a temperature of the coupled heat transfer member, and a discharge flow path part configured to discharge the cooling fluid to the outside of the internal space.

The deformable member includes a bimetal made by coupling two metals having different coefficients of thermal expansion.

The bimetal may include a first metal coupled to the heat transfer member and a second metal coupled to the first metal, and a coefficient of thermal expansion of the first metal may be lower than a coefficient of thermal expansion of the second metal.

The deformable member may be deformed in a direction in which the deformable member presses the heat transfer member when the temperature of the coupled heat transfer member increases.

The hygroscopic member may include a porous member configured to absorb the cooling fluid.

The deformable member may include one end coupled to the heat transfer member and the other end coupled to a protruding portion formed on the heat transfer member mounting part.

The heat transfer member may include first and second heat transfer members coupled to each other while facing each other, and the internal space is formed between the first and second heat transfer members.

The fluid supply part may be coupled to the first heat transfer member, and the discharge flow path part may be provided in the second heat transfer member.

The fluid supply part may include a fluid supply pipe having therein a passageway through which the cooling fluid passes.

The second heat transfer member may have a groove portion into which the hygroscopic member is inserted.

An inclined surface may be formed at an edge of the groove portion and inclined at a predetermined angle.

The first heat transfer member may include a protruding portion protruding by a predetermined interval toward the hygroscopic member.

A connection flow path may be formed in an inner surface of the second heat transfer member and connect the internal space and the groove portion.

The connection flow path may include a first flow path configured to connect the internal space and a corner of the groove portion and a second flow path configured to connect the internal space and an edge of the groove portion.

The second flow path may include a second main flow path connected to the internal space and extending along the edge of the groove portion and a second sub-flow path configured to connect the second main flow path and the edge of the groove portion.

The discharge flow path part may include an inner discharge flow path formed in an inner surface of the groove portion, a through-hole connected to the inner discharge flow path and formed through the groove portion, and an outer discharge flow path connected to the through-hole and formed in an outer surface of the second heat transfer member.

The outer discharge flow path may include a plurality of straight flow paths connected to the through-hole and a curved flow path connected to each of the plurality of straight flow paths.

A plurality of curved flow paths may be connected to one straight flow path.

The through-hole may be formed at a center of the groove portion.

The hygroscopic member may be provided as a plurality of hygroscopic members provided in the internal space.

The deformable member may include a first deformable member provided at an upper side of each of the hygroscopic members and a second deformable member provided at a lower side of each of the hygroscopic members.

The heat transfer member mounting part may have an opening into which the heat transfer member is inserted.

A sealing member may be interposed between the heat transfer member and the heat transfer member mounting part.

The heat exchange unit according to an embodiment of the present disclosure may discharge the cooling fluid, which is absorbed by the hygroscopic member, to the discharge flow path part when the temperature of the heat transfer member increases. Therefore, there is an advantageous effect of naturally cooling the heat transfer member and the surroundings, where the heat transfer member is installed, without using electric power.

The heat exchange unit according to another embodiment of the present disclosure includes the pair of first and second deformable members provided above and below the hygroscopic member. Therefore, there is an advantageous effect of effectively pressing the hygroscopic member and quickly discharging the cooling fluid stored in the hygroscopic member.

The heat exchange unit according to still another embodiment of the present disclosure includes the protruding portion protruding from one surface of the first heat transfer member in the direction toward the hygroscopic member. Therefore, there is an advantageous effect of increasing the pressing force to be transmitted to the hygroscopic member.

### BRIEF DESCRIPTION OF THE DRAWINGS

FIG. 1 is a perspective view of a heat exchange unit according to embodiments of the present disclosure.

FIG. 2 is a view for explaining an internal structure of the heat exchange unit according to embodiments of the present disclosure.

FIG. 3 is a top plan view of the heat exchange unit illustrated in FIG. 1.

FIG. 4 is a bottom plan view of the heat exchange unit illustrated in FIG. 1.

FIG. 5 is a right side view of the heat exchange unit illustrated in FIG. 1.

FIG. 6 is a view for explaining a structure of a connection flow path in the heat exchange unit according to embodiments of the present disclosure.

FIG. 7 is a view for explaining a structure of an outer discharge flow path in the heat exchange unit according to embodiments of the present disclosure.

### DETAILED DESCRIPTION OF ILLUSTRATIVE EMBODIMENTS

Hereinafter, a heat exchange unit according to embodiments of the present disclosure will be described with reference to the drawings.

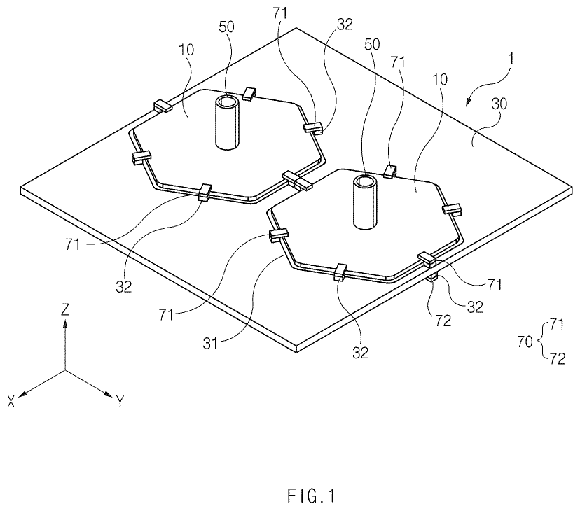

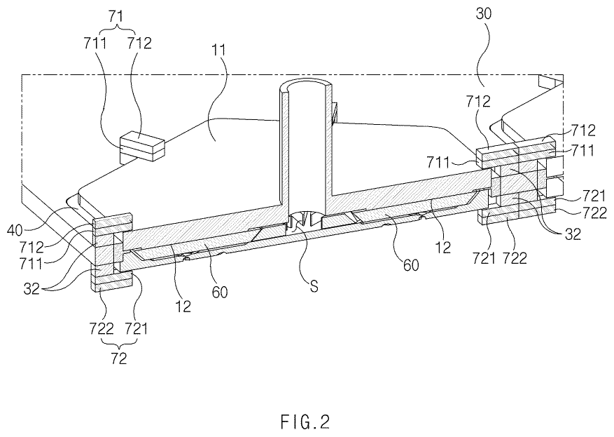

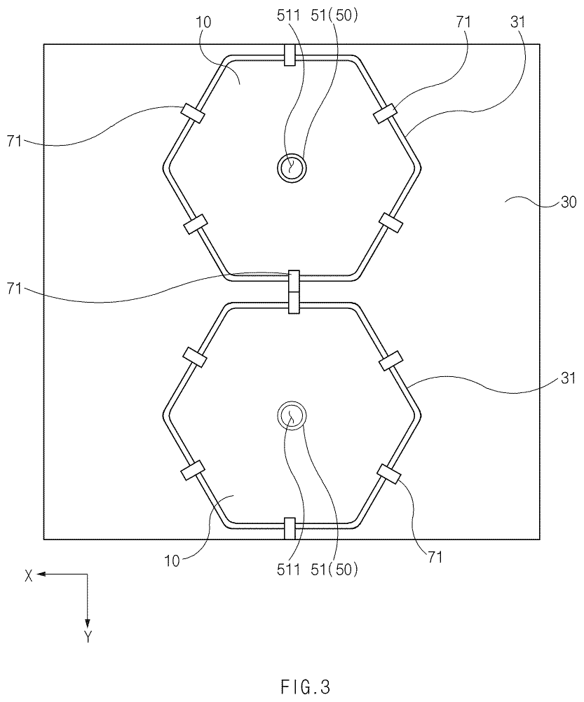

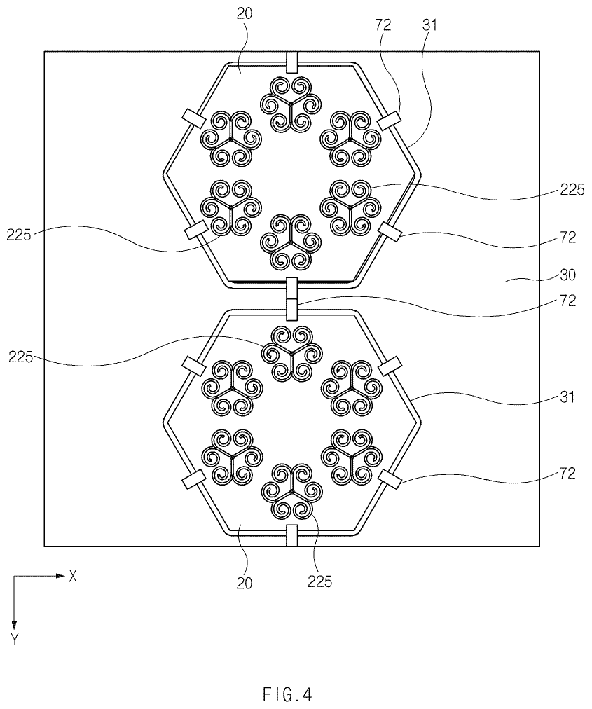

FIG. 1 is a perspective view of a heat exchange unit according to embodiments of the present disclosure, and FIG. 2 is a view for explaining an internal structure of the heat exchange unit according to embodiments of the present disclosure. In addition, FIG. 3 is a top plan view of the heat exchange unit illustrated in FIG. 1, and FIG. 4 is a bottom plan view of the heat exchange unit illustrated in FIG. 1.

With reference to FIGS. 1 to 4, a heat exchange unit 1 according to embodiments of the present disclosure may include a first and/or second heat transfer member 10 and/or 20 configured to define an internal space S to which a cooling fluid is supplied, a heat transfer member mounting part 30 on which the first and/or second heat transfer member 10 and/or 20 is mounted, a fluid supply part 50 configured to supply the cooling fluid to the internal space S, a hygroscopic member 60 provided in the internal space S and configured to absorb the cooling fluid supplied to the internal space S, deformable members 70 coupled to the first and/or second heat transfer member 10 and/or 20 and configured to be deformed in shape in response to a temperature of the first and/or second heat transfer member 10 and/or 20 to which the deformable members 70 are coupled, and a discharge flow path part configured to discharge the cooling fluid to the outside of the internal space S.

The heat exchange unit 1 refers to a heat exchange device mounted in various devices, such as a vehicle, a robot, and an electronic product, and configured to exchange heat with the corresponding device. The heat exchange unit 1 may include the first and/or second heat transfer member 10 and/or 20 configured to define the internal space S to which the cooling fluid is supplied. The first and second heat transfer members 10 and 20 may define the internal space S in various ways. For example, although not illustrated in the drawings, one heat transfer member may be coupled to a metal plate with a plate surface shape. The heat transfer member and the metal plate may be coupled to each other with a sealed predetermined space interposed therebetween. The corresponding sealed space may be the internal space S to which the cooling fluid is supplied.

In addition, as illustrated in FIGS. 1 and 2, the first and second heat transfer members 10 and 20 may be coupled to each other while facing each other and define the internal space S. The predetermined sealed space S may be formed between the first and second heat transfer members 10 and 20 coupled to each other. In this case, the first and second heat transfer members 10 and 20 may be coupled in various ways. For example, the pair of heat transfer members 10 and 20 may be coupled by a screw, a fixing pin, a bonding agent, or the like.

The first and second heat transfer members 10 and 20 may be mounted on the heat transfer member mounting part 30 in the state in which the first and second heat transfer members 10 and 20 are coupled to each other. In this case, the first heat transfer member 10, which is positioned at one side, and the second heat transfer member 20, which is positioned at the other side, may have different shapes. For example, the first heat transfer member 10 may have an angular or circular plate shape having a plate surface portion 11 and protruding portions 12 formed on the plate surface portion 11. In addition, the second heat transfer member 20 may have an angular or circular plate shape having one surface in which connection flow paths 21 and groove portions 22, which will be described below, are formed. In this case, the first heat transfer member 10 and the second heat transfer member 20 may have the same cross-sectional area.

The heat transfer member mounting part 30 is a member on which the heat transfer members 10 and 20 are mounted. The heat transfer member mounting part 30 may have various shapes. For example, the heat transfer member mounting part 30 may have a plate surface shape having one or more openings 31. The first heat transfer member 10 or the second heat transfer member 20, which is coupled to the metal plate, may be inserted into the opening 31. In addition, in the state in which the first and second heat transfer members 10 and 20 are coupled to each other, the first and second heat transfer members 10 and 20 may be inserted into each of the openings 31.

The heat transfer members 10 and 20 may be coupled to the heat transfer member mounting part 30 in various ways. For example, in case that the first and second heat transfer members 10 and 20 are inserted into the heat transfer member mounting part 30 in the state in which the first and second heat transfer members 10 and 20 are coupled to each other, one or more protruding portions 32 may be formed on each of one surface and the other surface of the heat transfer member mounting part 30, and the protruding portions 32 and the heat transfer members 10 and 20 are coupled by deformable members 71 and 72 to be described below.

In addition, in case that any one of the first and second heat transfer members 10 and 20 is coupled to the metal plate having a plate surface shape as described above, a coupled body, which is made by coupling any one of the first and second heat transfer members 10 and 20 and the plate surface, may be inserted into the heat transfer member mounting part 30. In this case, any one of the first and second heat transfer members 10 and 20 and the plate surface may be connected to the protruding portions 32 respectively formed on two opposite surfaces of the heat transfer member mounting part 30.

The fluid supply part 50 may be variously configured to supply the cooling fluid, such as a coolant, liquid ammonia, or liquid Freon, to the internal space S. For example, the fluid supply part 50 may be coupled to at least one of the heat transfer members 10 and 20 coupled to each other. The fluid supply part 50 may include a fluid supply pipe 51 having a passageway 511 therein, and a discharge port of the fluid supply pipe 51 may be connected to the internal space S.

One or more hygroscopic members 60 may be provided in the internal space S and absorb the cooling fluid supplied to the internal space S. The hygroscopic members 60 may be provided at various positions in the internal space S. For example, in case that the internal space S is defined between the first and second heat transfer members 10 and 20, the hygroscopic members 60 may be respectively inserted into the groove portions 22 that are formed in one surface of the second heat transfer member 20 and will be described below. The hygroscopic member 60 may have various structures. For example, the hygroscopic member 60 may have a structure corresponding to a shape of the groove portion 22 into which the hygroscopic member 60 is inserted.

The deformable members 70 are coupled to the heat transfer members 10 and 20 and deformed in shapes in response to the temperatures of the coupled heat transfer members 10 and 20. The deformable members 70 may include a first deformable member 71 coupled to the first heat transfer member 10 and a second deformable member 72 coupled to the second heat transfer member 20.

The first and second deformable members 71 and 72 may be deformed in shapes when the temperatures of the coupled heat transfer members 10 and 20 are changed. The deformed shapes may press the coupled heat transfer members 10 and 20. In this case, the hygroscopic member 60 provided between the coupled heat transfer members 10 and 20 may be pressed by the heat transfer members 10 and 20 and discharge the stored cooling fluid to the discharge flow path part provided in at least one of the pair of heat transfer members 10 and 20.

As described above, the heat exchange unit 1 according to embodiments of the present disclosure includes the hygroscopic members 60 provided between the heat transfer members 10 and 20 and the deformable members 70 coupled to the heat transfer members 10 and 20 and configured to be deformed in shape in response to the temperatures of the coupled heat transfer members 10 and 20, and the heat exchange unit 1 according to embodiments of the present disclosure has the structure in which the discharge flow path part is provided in at least one of the heat transfer members 10 and 20. Therefore, when the temperatures of the heat transfer members 10 and 20 are changed, the deformable members 70 may press the heat transfer members 10 and 20, such that the cooling fluid stored in the hygroscopic members 60 may be discharged to the discharge flow path part.

In this case, the cooling fluid may be vaporized by absorbing surrounding heat while passing through the discharge flow path part, such that an operator may naturally cool the device, in which the heat transfer members 10 and 20 are installed, without using separate electric power. That is, according to the heat exchange unit 1 according to embodiments of the present disclosure, it is not necessary to connect a power source to the heat transfer member 10. Therefore, there is an advantageous effect of reducing the number of constituent elements and assembling processes required to install the heat exchange unit 1 and simplifying the layout of the heat exchange unit 1.

Meanwhile, a sealing member 40 may be interposed between the pair of heat transfer members 10 and 20 and the heat transfer member mounting part 30. For example, the pair of heat transfer members 10 and 20 may be inserted into the opening 31 formed in the heat transfer member mounting part 30, and the sealing member 40 may be interposed between lateral surfaces of the heat transfer members 10 and 20 and a sidewall of the opening 31.

The sealing member 40 may be variously configured to seal a lateral surface of the internal space S. For example, an elastomer, such as an O-ring, may be used as the sealing member 40.

Meanwhile, the hygroscopic member 60 may be configured to absorb the cooling fluid and may be made of various materials. For example, the hygroscopic member 60 may be a porous member configured to absorb the cooling fluid. The hygroscopic member 60 may be a porous elastomer configured to discharge the cooling fluid while being contracted by being pressed. The porous elastomer may include a sponge.

The first and second deformable members 71 and 72 may each be a bimetal made by coupling two metals having different coefficients of thermal expansion. The bimetals may include first metals 711 and 721 coupled directly to the first and second heat transfer members 10 and 20 and second metals 712 and 722 coupled to the first metals 711 and 721. That is, the first and second deformable members 71 and 72 may each have a stacked structure in which different metals are stacked in two layers.

In addition, when the temperatures of the coupled heat transfer members 10 and 20 increase, the first and second deformable members 71 and 72 may be deformed in a direction in which the first and second deformable members 71 and 72 press the corresponding heat transfer members 10 and 20. For example, a coefficient of thermal expansion of the first metals 711 and 721 may be lower than a coefficient of thermal expansion of the second metals 712 and 722.

When the coefficient of thermal expansion of the first metals 711 and 721 is lower than the coefficient of thermal expansion of the second metals 712 and 722, the first metals 711 and 721 expand less than the second metals 712 and 722 when the temperatures of the heat transfer members 10 and 20 increase. In this case, the first and second deformable members 71 and 72 press the heat transfer members 10 and 20 while being bent toward the first metals 711 and 721.

In this case, the heat transfer members 10 and 20 may move toward each other and press the hygroscopic members 60 interposed between the heat transfer members 10 and 20. The hygroscopic member 60 may discharge the absorbed cooling fluid to the discharge flow path part while being contracted by being pressed.

Specifically, the first heat transfer member 10 may absorb heat from the heating element or the like of the electronic device and transfer the heat to the cooling fluid provided in the internal space S between the first and second heat transfer members 10 and 20. The cooling fluid, which receives the heat from the first heat transfer member 10, may be discharged to the outside through the discharge flow path part provided in the second heat transfer member 20. That is, the first heat transfer member 10 may be a member configured to absorb heat from the heating element or the like of the electronic device and transfer the heat to the cooling fluid. The second heat transfer member 20 may be a member configured to transfer the heat of the cooling fluid to the outside.

Meanwhile, the hygroscopic members 60 may be provided as a plurality of hygroscopic members 60 provided between the pair of heat transfer members 10 and 20. For example, the pair of heat transfer members 10 and 20 may each have a hexagonal plate surface shape, and six hygroscopic members 60 each having a triangular cross-section may be provided between the pair of heat transfer members 10 and 20. In this case, the hygroscopic members 60 may be disposed at equal intervals.

The deformable members 70 may include the first deformable members 71 respectively provided at upper sides of the hygroscopic members 60 and the second deformable members 72 respectively provided at lower sides of the hygroscopic members 60. That is, the first deformable members 71 and the second deformable members 72 may each be provided to correspond in number to the hygroscopic members 60.

The first deformable member 71 may be coupled to the first heat transfer member 10 positioned at the upper side, and the second deformable member 72 may be coupled to the second heat transfer member 20 positioned at the lower side. In addition, in case that six hygroscopic members 60 are interposed between the first and second heat transfer members 10 and 20, six first deformable members 71 may be coupled to the first heat transfer member 10, and six second deformable members 72 may be coupled to the second heat transfer member 20.

That is, the first and second deformable members 71 and 72 are provided one by one at the upper and lower sides of one hygroscopic member 60, respectively. When the temperatures of the heat transfer members 10 and 20 are changed, the pair of first and second deformable members 71 and 72 may be deformed in shape and press the hygroscopic member 60 positioned between the pair of first and second deformable members 71 and 72. In this case, because the hygroscopic member 60 is pressed by the pair of first and second deformable members 71 and 72 provided above and below the hygroscopic member 60, the hygroscopic member 60 may be effectively pressed, and the cooling fluid stored in the hygroscopic member 60 may be quickly discharged.

Meanwhile, the first heat transfer member 10 may have the protruding portion 12 protruding by a predetermined interval toward the hygroscopic members 60. Specifically, the protruding portion 12 may protrude from a lower surface of the first heat transfer member 10 in a direction toward the hygroscopic member 60. When the pair of heat transfer members 10 and 20 are pressed by the deformable members 71 and 72, the protruding portions 12 may transmit a higher pressing force to the hygroscopic members 60. In case that the protruding portions 12 are formed on the first heat transfer member 10 as described above, the pressing force to be transmitted to the hygroscopic members 60 may be increased, and the hygroscopic members 60 may be effectively pressed.

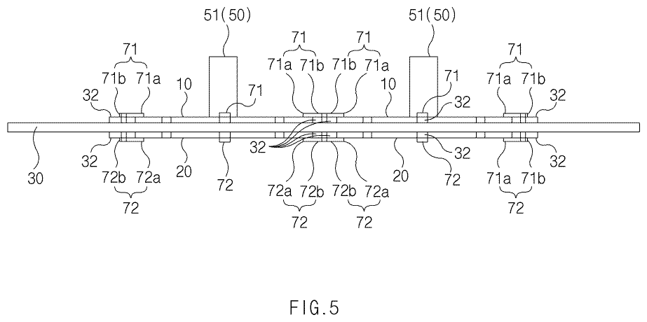

FIG. 5 is a right side view of the heat exchange unit illustrated in FIG. 1.

With reference to FIG. 5, the deformable members 71 and 72 may include first ends 71a and 72a coupled to the heat transfer members 10 and 20 and second ends 71b and 72b coupled to the protruding portions 32 formed on the heat transfer member mounting part 30. In this case, the first end 71a of the first deformable member 71 may be coupled to the first heat transfer member 10, and the second end 71b of the first deformable member 71 may be coupled to the protruding portion 32 formed on the upper surface of the heat transfer member mounting part 30. In addition, the first end 72a of the second deformable member 72 may be coupled to the second heat transfer member 20, and the second end 72b of the second deformable member 72 may be coupled to the protruding portion 32 formed on the lower surface of the heat transfer member mounting part 30.

The deformable members 71 and 72 may be coupled to the heat transfer members 10 and 20 and the protruding portions 32 in various ways. For example, the deformable members 71 and 72 may be coupled to the heat transfer members 10 and 20 and the protruding portions 32 by welding. In addition, bonding layers may be formed by a bonding agent between the deformable members 71 and 72, the heat transfer members 10 and 20, and the protruding portions 32.

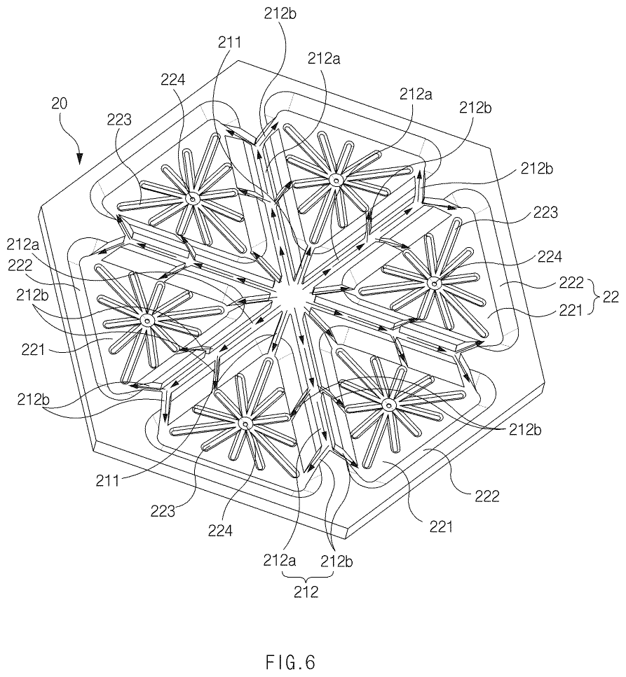

FIG. 6 is a view for explaining a structure of a connection flow path in the heat exchange unit according to embodiments of the present disclosure.

With reference to FIG. 6, the connection flow paths 21 may be formed in the inner surface of the second heat transfer member 20 and connect the internal space S and the groove portions 22. The connection flow paths 21 may include first flow paths 211 configured to connect the internal space S and corners of the groove portions 22 and second flow paths 212 configured to connect the internal space S and edges of the groove portions 22.

In this case, the first flow path 211 may have various shapes. For example, the first flow path 211 may be connected to the corner closest to the internal space S among the corners of the groove portion 22. In addition, the plurality of groove portions 22 and the plurality of first flow paths 211 may be formed in the inner surface of the second heat transfer member 20, and the groove portions 22 and the first flow paths 211 may be equal in number.

Like the first flow path 211, the second flow path 212 may also have various shapes. For example, the second flow path 212 may extend along the edge of the groove portion 22 and be connected to the edge portion of the groove portion 22. Specifically, the second flow path 212 may include a second main flow path 212a connected to the internal space S and extending along the edge of the groove portion 22 and a second sub-flow path 212b configured to connect the second main flow path 212a and the edge of the groove portion 22.

In addition, the second main flow paths 212a extend along two opposite edges of each of the plurality of groove portions 22 formed in the inner surface of the second heat transfer member 20. The plurality of second sub-flow paths 212b may be connected to one second main flow path 212a. That is, the second main flow paths 212a and the second sub-flow paths 212b may be formed over an entire plate surface portion where the groove portions 22 are not formed in the inner surface of the second heat transfer member 20.

FIG. 6 illustrates a plurality of arrows indicating flows of the cooling fluid supplied to the internal space S. The cooling fluid, which is supplied to the internal space S between the first and second heat transfer members 10 and 20 through the fluid supply part 50, may flow along the first flow paths 211 and the second flow paths 212 formed widely over the entire plate surface portion of the second heat transfer member 20. The cooling fluid may be introduced into the groove portions 22 through the first flow paths 211 and the second flow paths 212, and the hygroscopic members 60 provided in the groove portions 22 may absorb the cooling fluid.

Because the first flow paths 211 and the second flow paths 212 are widely formed over the entire plate surface portion of the second heat transfer member 20 as described above, the cooling fluid supplied to the internal space S may be uniformly supplied to the plurality of hygroscopic members 60. In this case, there is an advantageous effect of evenly supplying the cooling fluid to the hygroscopic members 60 without concentrating the cooling fluid only on a single hygroscopic member 60.

Meanwhile, an inclined surface 222, which is inclined at a predetermined angle, may be formed at the edge of each of the groove portions 22 formed in the second heat transfer member 20. The inclined surface 222 may be formed to be gently inclined toward a flat surface 221 of the groove portion 22. The first flow path 211 and the second sub-flow path 212b may be formed in the inclined surface 222.

In addition, the second heat transfer member 20 may be formed with the discharge flow path part configured to discharge the cooling fluid, which is absorbed by the hygroscopic member 60, to the outside. The discharge flow path part may include inner discharge flow paths 223 formed in an inner surface of the groove portion 22, a through-hole 224 connected to the inner discharge flow paths 223 and formed through the groove portion 22, and outer discharge flow paths 225 connected to the through-hole 224 and formed in the outer surface of the second heat transfer member 20.

The inner discharge flow path 223 may be formed in the flat surface 221 of the groove portion 22 and have various shapes. As illustrated in FIG. 6, the inner discharge flow paths 223 may be formed over an entire area of the flat surface 221 of the groove portion 22.

The through-hole 224 may be an opening formed through the flat surface 221 of the groove portion 22 and formed at various positions on the flat surface 221. For example, the through-hole 224 may be formed at a center of the flat surface 221 of the groove portion 22, and the plurality of inner discharge flow paths 223 may be connected to the through-hole 224.

When the hygroscopic member 60 is pressed by the deformable members 71 and 72, the cooling fluid absorbed by the hygroscopic member 60 may pass through the inner discharge flow paths 223 formed in the flat surface 221 of the groove portion 22 and through the through-hole 224. The cooling fluid having passed through the through-hole 224 may be discharged to the outer discharge flow paths 225 connected to the through-hole 224.

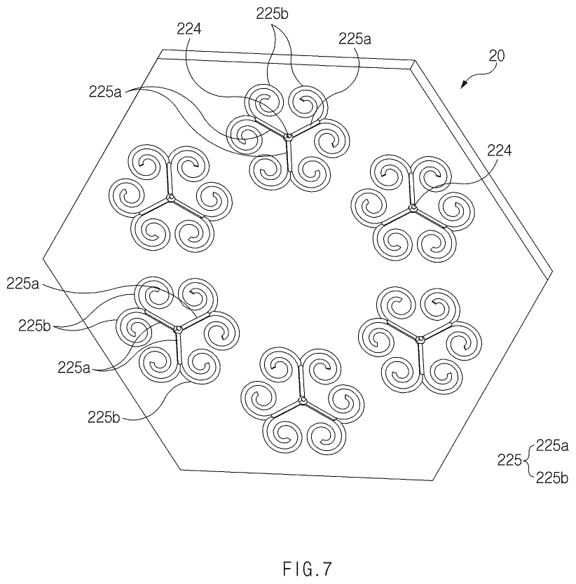

FIG. 7 is a view for explaining a structure of the outer discharge flow path in the heat exchange unit according to embodiments of the present disclosure. With reference to FIG. 7, the plurality of outer discharge flow paths 225 may be formed in the outer surface of the second heat transfer member 20. The outer discharge flow paths 225 may each include a plurality of straight flow paths 225a connected to the through-hole 224 and curved flow paths 225b connected to the straight flow paths 225a.

In this case, the plurality of curved flow paths 225b may be connected to each of the straight flow paths 225a. For example, as illustrated in FIG. 7, one outer discharge flow path 225 may include three straight flow paths 225a, and two curved flow paths 225b may be connected to each of the straight flow paths 225a.

Meanwhile, the curved flow path 225b may have various shapes. For example, as illustrated in FIG. 7, the adjacent curved flow paths 225b may have spiral structures curved in opposite directions. In case that the adjacent curved flow paths 225b have the spiral structures curved in the opposite directions as described above, the curved flow paths 225b have large surface areas, which may facilitate the vaporization of the cooling fluid passing through the curved flow paths 225b. The vaporization of the cooling fluid is an endothermic reaction. In case that the curved flow path 225b has the above-mentioned spiral structure, the endothermic reaction may be promoted, which may effectively cool the surroundings.

Embodiments of the present disclosure have been described with reference to the exemplary embodiments and the drawings, but the present disclosure is not limited thereby. The present disclosure may be carried out in various forms by those skilled in the art, to which the present disclosure pertains, within the technical spirit of the present disclosure and the scope equivalent to the appended claims.

What is claimed is:

1. A heat exchange system comprising:
a heat transfer member mounting part;
a heat transfer member mounted on the heat transfer member mounting part and defining an internal space;
a fluid supply part configured to supply a cooling fluid to the internal space;
a hygroscopic member disposed in the internal space and configured to absorb the cooling fluid supplied to the internal space;
a deformable member coupled to the heat transfer member and configured to be deformed in shape in response to a temperature of the heat transfer member; and
a discharge flow path part configured to discharge the cooling fluid from the internal space.

2. The heat exchange system of claim 1, wherein the deformable member comprises a bimetal comprising two metals coupled together, the two metals having different coefficients of thermal expansion.

3. The heat exchange system of claim 2, wherein:
the bimetal comprises:
a first metal coupled to the heat transfer member; and
a second metal coupled to the first metal; and
the coefficient of thermal expansion of the first metal is lower than the coefficient of thermal expansion of the second metal.

4. The heat exchange system of claim 1, wherein the deformable member is configured to be deformed in a direction in which the deformable member presses the heat transfer member in a case in which the temperature of the heat transfer member increases.

5. The heat exchange system of claim 1, wherein the hygroscopic member comprises a porous member configured to absorb the cooling fluid.

6. The heat exchange system of claim 1, wherein the deformable member comprises:
a first end coupled to the heat transfer member; and
a second end coupled to a protruding portion disposed on the heat transfer member mounting part.

7. The heat exchange system of claim 1, wherein the hygroscopic member comprises a plurality of hygroscopic members disposed in the internal space.

8. The heat exchange system of claim 7, wherein the deformable member comprises:
a first deformable member disposed at an upper side of each of the hygroscopic members; and
a second deformable member disposed at a lower side of each of the hygroscopic members.

9. The heat exchange system of claim 1, wherein the heat transfer member mounting part has an opening into which the heat transfer member is inserted.

10. The heat exchange system of claim 9, further comprising a sealing member interposed between the heat transfer member and the heat transfer member mounting part.

11. A heat exchange system comprising:
a heat transfer member mounting part;
a heat transfer member mounted on the heat transfer member and comprising first and second heat transfer members coupled to each other while facing each other, wherein an internal space is defined between the first and second heat transfer members;
a fluid supply part configured to supply a cooling fluid to the internal space;
a hygroscopic member disposed in the internal space and configured to absorb the cooling fluid supplied to the internal space;
a deformable member coupled to the heat transfer member and configured to be deformed in shape in response to a temperature of the heat transfer member; and
a discharge flow path part configured to discharge the cooling fluid from the internal space.

12. The heat exchange system of claim 11, wherein:
the fluid supply part is coupled to the first heat transfer member; and
the discharge flow path part is disposed in the second heat transfer member.

13. The heat exchange system of claim 12, wherein the fluid supply part comprises a fluid supply pipe having therein a passageway through which the cooling fluid passes.

14. The heat exchange system of claim 12, wherein the second heat transfer member has a groove portion into which the hygroscopic member is inserted.

15. The heat exchange system of claim 14, wherein an inclined surface is disposed at an edge of the groove portion and inclined at a predetermined angle.

16. The heat exchange system of claim 14, wherein the first heat transfer member comprises a protruding portion protruding by a predetermined interval toward the hygroscopic member.

17. The heat exchange system of claim 14, further comprising a connection flow path disposed in an inner surface of the second heat transfer member and connecting the internal space and the groove portion.

18. The heat exchange system of claim 17, wherein the connection flow path comprises:
a first flow path connecting the internal space and a corner of the groove portion; and
a second flow path connecting the internal space and an edge of the groove portion.

19. The heat exchange system of claim 18, wherein the second flow path comprises:
a second main flow path connected to the internal space and extending along the edge of the groove portion; and
a second sub-flow path connecting the second main flow path and the edge of the groove portion.

20. The heat exchange system of claim 14, wherein the discharge flow path part comprises:
an inner discharge flow path disposed in an inner surface of the groove portion;
a through-hole connected to the inner discharge flow path and extending through the groove portion; and
an outer discharge flow path connected to the through-hole and disposed in an outer surface of the second heat transfer member.

21. The heat exchange system of claim 20, wherein the outer discharge flow path comprises:
a plurality of straight flow paths connected to the through-hole; and
a curved flow path connected to each of the plurality of straight flow paths.

22. The heat exchange system of claim 17, wherein a plurality of curved flow paths is connected to one straight flow path.

23. The heat exchange system of claim 20, wherein the through-hole is disposed at a center of the groove portion.
